(19) United States
(12) Patent Application Publication
(10) Pub. No.: US 2026/0164656 A1
(43) Pub. Date: Jun. 11, 2026

(54) SEMICONDUCTOR MEMORY DEVICE

(71) Applicant: Kioxia Corporation, Tokyo (JP)

(72) Inventors: Shoto NODO, Yokkaichi Mie (JP); Shunichi SENO, Yokkaichi Mie (JP); Kouji MATSUO, Ama Aichi (JP); Shinya NAITO, Toyota Aichi (JP); Takashi KURUSU, Yokkaichi Mie (JP); Fumitaka ARAI, Yokkaichi Mie (JP)

(73) Assignee: Kioxia Corporation, Tokyo (JP)

(21) Appl. No.: 19/327,490

(22) Filed: Sep. 12, 2025

(30) Foreign Application Priority Data
Dec. 9, 2024 (JP) 2024-214555

(51) Int. Cl. H10B 41/35; H10B 41/10; H10B 41/20

(52) U.S. Cl. CPC H10B 41/35; H10B 41/10; H10B 41/20

(57) ABSTRACT

A semiconductor memory device comprises: semiconductor layers stacked in a stacking direction and extending in a first direction; conductive layers connected to end portions of the semiconductor layers; first via electrodes facing the semiconductor layers; and second via electrodes provided between the conductive layers and the first via electrodes, and facing the semiconductor layers. In a first cross section, a surface facing one of the semiconductor layers, of the second via electrode lies along a first circle, and a surface on an opposite side to the semiconductor layers, of the second via electrode lies along a second circle. In a second cross section, an outer peripheral surface of the second via electrode lies along a third circle. A radius of at least one of the first circle and the second circle differs from a radius of the third circle.

### CROSS-REFERENCE TO RELATED APPLICATIONS

This application is based upon and claims the benefit of Japanese Patent Application No. 2024-214555, filed on Dec. 9, 2024, the entire contents of which are incorporated herein by reference.

### BACKGROUND

### Field

The present embodiments relate to semiconductor memory devices.

### Description of the Related Art

There is known a semiconductor memory device comprising: a plurality of semiconductor layers stacked in a stacking direction and extending in a first direction intersecting the stacking direction; a plurality of via electrodes which are arranged in the first direction, extend in the stacking direction, and face the plurality of semiconductor layers; and a plurality of electric charge accumulating layers provided between the plurality of semiconductor layers and the plurality of via electrodes.

### BRIEF DESCRIPTION OF THE DRAWINGS

FIG. 1 is a schematic perspective view showing a configuration of a part of a semiconductor memory device according to a first embodiment;

FIG. 2 is a schematic circuit diagram showing a configuration of a part of same semiconductor memory device;

FIG. 3 is a schematic plan view showing a configuration of a part of a memory cell array layer L_{MCA};

FIG. 4 is a schematic cross-sectional view showing a configuration of a part of the memory cell array layer L_{MCA};

FIG. 5 is a schematic cross-sectional view showing a configuration of a part of the memory cell array layer L_{MCA};

FIG. 6 is a schematic plan view showing a configuration of a part of the memory cell array layer L_{MCA};

FIG. 7 is a schematic plan view showing a configuration of a part of the memory cell array layer L_{MCA};

FIG. 8 is a schematic circuit diagram for explaining a write operation of the semiconductor memory device according to the present embodiment;

FIG. 9 is a schematic plan view showing a configuration of a part of a semiconductor memory device according to a second embodiment;

FIG. 10 is a schematic plan view showing a configuration of a part of a semiconductor memory device according to a third embodiment;

FIG. 11 is a schematic plan view showing a configuration of a part of a semiconductor memory device according to a fourth embodiment;

FIG. 12 is a schematic plan view showing a configuration of a part of a semiconductor memory device according to a fifth embodiment;

FIG. 13 is a schematic plan view showing a configuration of a part of a semiconductor memory device according to a sixth embodiment;

FIG. 14 is a schematic plan view showing a configuration of a part of a semiconductor memory device according to a seventh embodiment;

FIG. 15 is a schematic plan view showing a configuration of a part of a semiconductor memory device according to an eighth embodiment;

FIG. 16 is a schematic plan view showing a configuration of a part of the semiconductor memory device according to the eighth embodiment;

FIG. 17 is a schematic plan view for explaining a method of manufacturing the semiconductor memory device according to the eighth embodiment;

FIG. 18 is a schematic plan view for explaining same method of manufacturing;

FIG. 19 is a schematic plan view for explaining same method of manufacturing;

FIG. 20 is a schematic plan view for explaining same method of manufacturing;

FIG. 21 is a schematic plan view for explaining same method of manufacturing; and

FIG. 22 is a schematic plan view showing a configuration of a part of a semiconductor memory device according to a ninth embodiment.

### DETAILED DESCRIPTION

A semiconductor memory device according to one embodiment comprises: a plurality of semiconductor layers and a plurality of insulating layers stacked alternately in a stacking direction and extending in a first direction intersecting the stacking direction; a plurality of conductive layers which are stacked in the stacking direction correspondingly to the plurality of semiconductor layers, extend in a second direction intersecting the stacking direction and the first direction, and are connected to end portions in the first direction of the plurality of semiconductor layers; a plurality of first via electrodes which are arranged in the first direction along side surfaces in the second direction of the plurality of semiconductor layers, extend in the stacking direction, and face the plurality of semiconductor layers; a plurality of electric charge accumulating layers provided between the plurality of semiconductor layers and the plurality of first via electrodes; and a plurality of second via electrodes which are provided between the plurality of conductive layers and the plurality of first via electrodes, are arranged in the first direction along side surfaces in the second direction of the plurality of semiconductor layers, extend in the stacking direction, and face the plurality of semiconductor layers. In a first cross section extending in the first direction and the second direction, and including one of the plurality of semiconductor layers, a surface facing the one of the plurality of semiconductor layers, of the second via electrode lies along a first circle, and a surface on an opposite side to the plurality of semiconductor layers, of the second via electrode lies along a second circle. In a second cross section extending in the first direction and the second direction, and including one of the plurality of insulating layers, an outer peripheral surface of the second via electrode lies along a third circle. A radius of at least one of the first circle and the second circle differs from a radius of the third circle.

Next, semiconductor memory devices according to embodiments will be described in detail with reference to the drawings. Note that the following embodiments are merely examples, and are not shown with the intention of limiting the present invention. Moreover, the following drawings are schematic, and, for convenience of description, parts of configurations, and so on, thereof will sometimes be omitted. Moreover, portions that are common to a plurality of embodiments will be assigned with the same symbols, and descriptions thereof sometimes omitted.

Moreover, when a “semiconductor memory device” is referred to in the present specification, it will sometimes mean a memory die, and will sometimes mean a memory system including a controller die, of the likes of a memory chip, a memory card, or an SSD (Solid State Drive). Furthermore, it will sometimes mean a configuration including a host computer, of the likes of a smartphone, a tablet terminal, or a personal computer.

Moreover, in the present specification, when a first configuration is said to be “electrically connected” to a second configuration, the first configuration may be connected to the second configuration directly, or the first configuration may be connected to the second configuration via the likes of a wiring, a semiconductor member, or a transistor. For example, in the case of three transistors having been connected in series, the first transistor is still “electrically connected” to the third transistor even when the second transistor is in an OFF state.

Moreover, in the present specification, when a first configuration is said to be “connected between” a second configuration and a third configuration, it will sometimes mean that the first configuration, the second configuration, and the third configuration are connected in series, and the second configuration is connected to the third configuration via the first configuration.

Moreover, in the present specification, when a circuit, or the like, is said to “make electrically conductive” two wirings, or the like, this will sometimes mean, for example, that this circuit, or the like, includes a transistor, or the like, that this transistor, or the like, is provided in a current path between the two wirings, and that this transistor, or the like, is in an ON state.

Moreover, in the present specification, a certain direction parallel to an upper surface of a substrate will be referred to as an X-direction, a direction parallel to the upper surface of the substrate and perpendicular to the X-direction will be referred to as a Y-direction, and a direction perpendicular to the upper surface of the substrate will be referred to as a Z-direction.

Moreover, in the present specification, a direction lying along a certain plane will sometimes be referred to as a first direction, a direction intersecting the first direction along this certain plane will sometimes be referred to as a second direction, and a direction intersecting this certain plane will sometimes be referred to as a third direction. These first direction, second direction, and third direction may correspond to any of the Y-direction, the X-direction, and the Z-direction, but need not do so.

Moreover, in the present specification, expressions such as “above” or “below” will be defined with reference to the substrate. For example, an orientation of moving away from the substrate along the above-described Z-direction will be referred to as above, and an orientation of coming closer to the substrate along the Z-direction will be referred to as below. Moreover, when a lower surface or a lower end is referred to for a certain configuration, this will be assumed to mean a surface or end portion on a substrate side of this configuration, and when an upper surface or an upper end is referred to for a certain configuration, this will be assumed to mean a surface or end portion on an opposite side to the substrate of this configuration. Moreover, a surface intersecting the X-direction or the Y-direction will be referred to as a side surface, and so on.

### First Embodiment

### [Configuration]

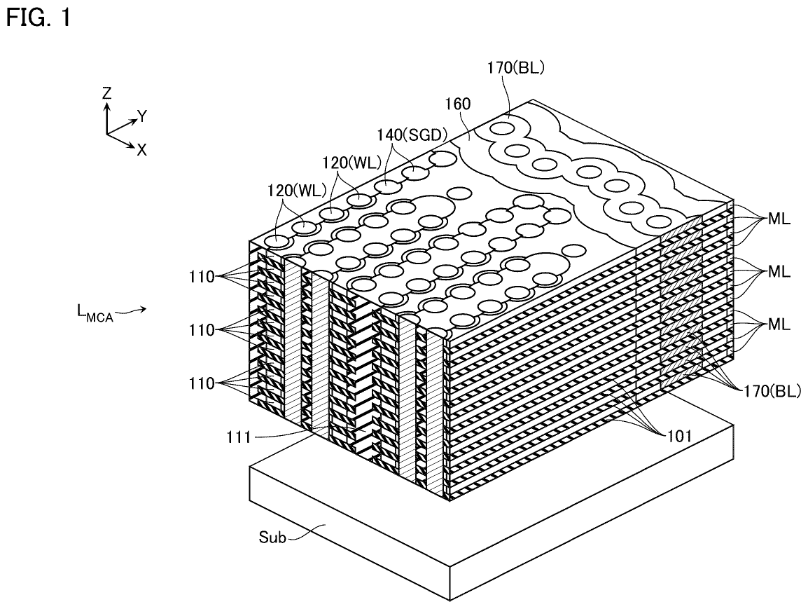

FIG. 1 is a schematic perspective view showing a configuration of a part of a semiconductor memory device according to a first embodiment. The semiconductor memory device according to the present embodiment comprises: a semiconductor substrate Sub; and a memory cell array layer L_{MCA} provided above the semiconductor substrate Sub.

The semiconductor substrate Sub is a semiconductor substrate of the likes of silicon (Si) including a P-type impurity such as boron (B), for example. At least a part of a peripheral circuit for controlling configurations in the memory cell array layer L_{MCA} may be provided on an upper surface of the semiconductor substrate Sub.

The memory cell array layer L_{MCA} comprises a plurality of memory layers ML and a plurality of insulating layers 101 that are stacked alternately in the Z-direction. The insulating layer 101 includes the likes of silicon oxide (SiO₂), for example.

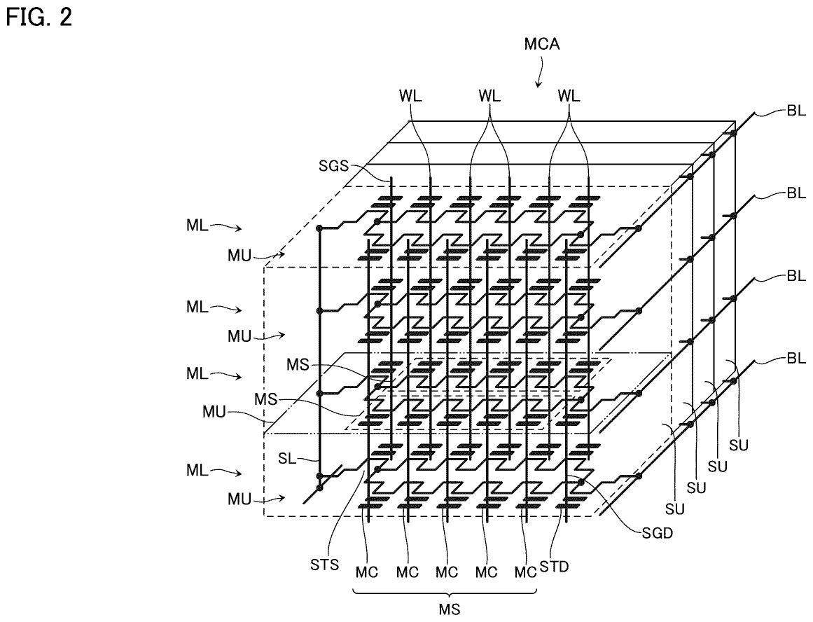

FIG. 2 is a schematic circuit diagram showing a configuration of a part of the semiconductor memory device according to the present embodiment.

The memory cell array layer L_{MCA} according to the present embodiment functions as a memory cell array MCA. The memory cell array MCA comprises a plurality of string units SU. The string units SU each comprise a plurality of memory units MU provided correspondingly to the plurality of memory layers ML. The plurality of memory units MU each comprise two memory strings MS. These two memory strings MS each comprise a plurality of memory cells MC (memory transistors) connected in series. One ends of these two memory strings MS are connected to a bit line BL via a common drain side select transistor STD. Moreover, the other ends of these two memory strings MS are connected to a source line SL via a common source side select transistor STS. Hereafter, the drain side select transistor STD and the source side select transistor STS will sometimes simply be referred to as select transistors STD, STS.

The memory cell MC is a field effect type transistor. The memory cell MC comprises a semiconductor layer, a gate insulating layer, and a gate electrode. The semiconductor layer functions as a channel region. The gate insulating layer includes an electric charge accumulating layer. Threshold voltage of the memory cell MC changes according to an amount of electric charge in the electric charge accumulating layer. The memory cell MC stores 1 bit or a plurality of bits of data. Note that the gate electrodes of the plurality of memory cells MC included in one memory unit MU are each connected with word lines WL. These word lines WL are each commonly connected to all of the memory units MU in the plurality of string units SU.

The select transistors STD, STS are each a field effect type transistor. The select transistors STD, STS each comprise a semiconductor layer, a gate insulating layer, and a gate electrode. The semiconductor layer functions as a channel region. The gate electrodes of the select transistors STD, STS are respectively connected with select gate lines SGD, SGS. The drain side select gate lines SGD are each commonly connected to all of the memory units MU in their corresponding string units SU. The source side select gate lines SGS are each commonly connected to all of the memory units MU in their corresponding string units SU.

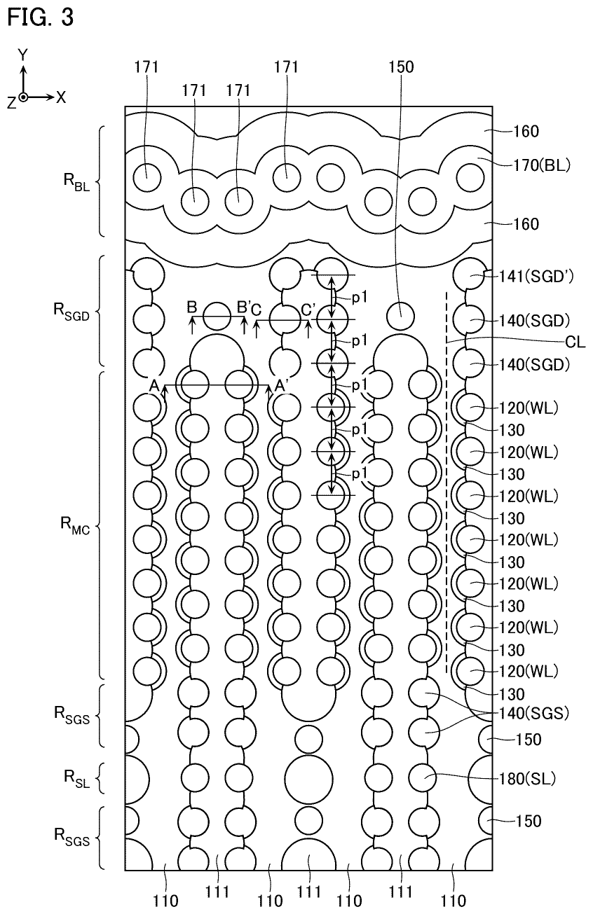

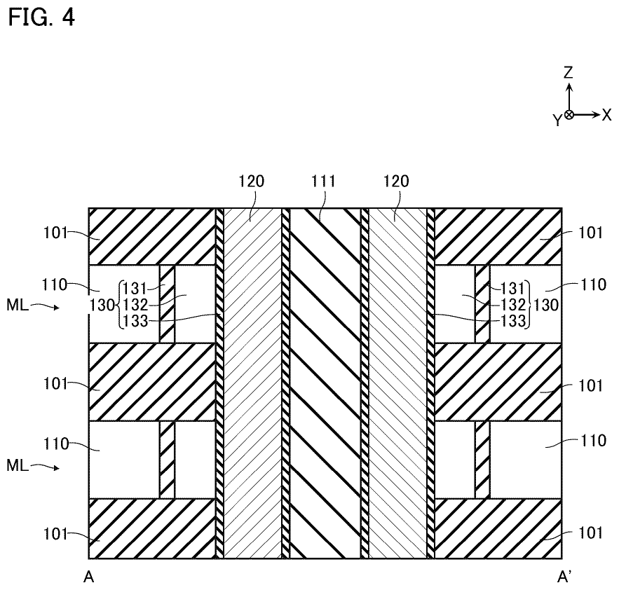

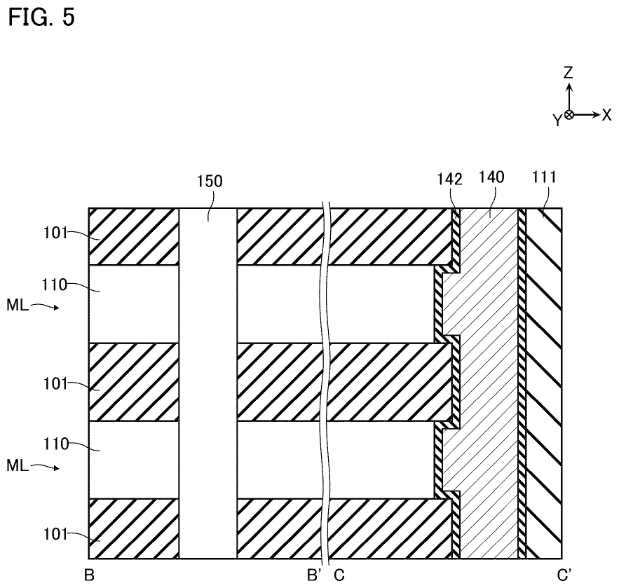

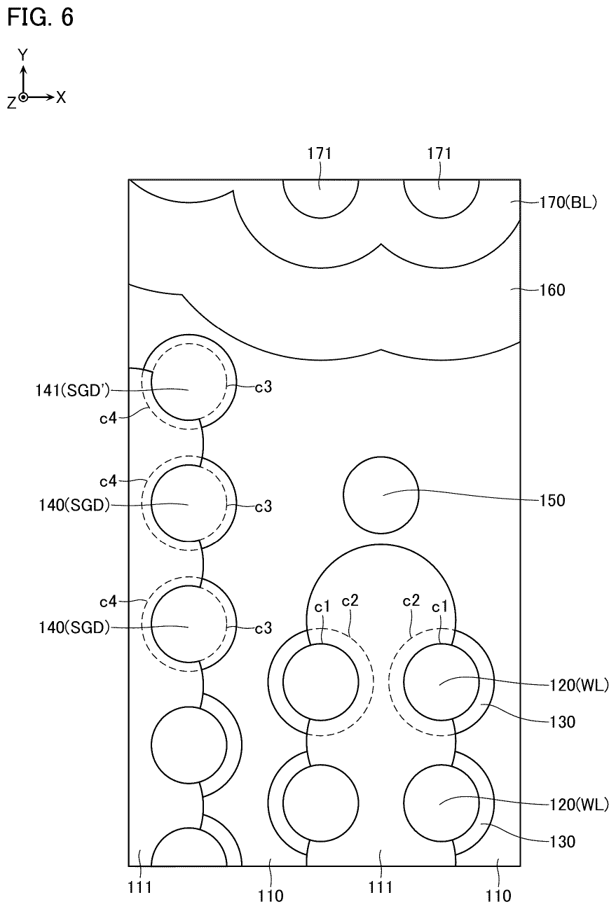

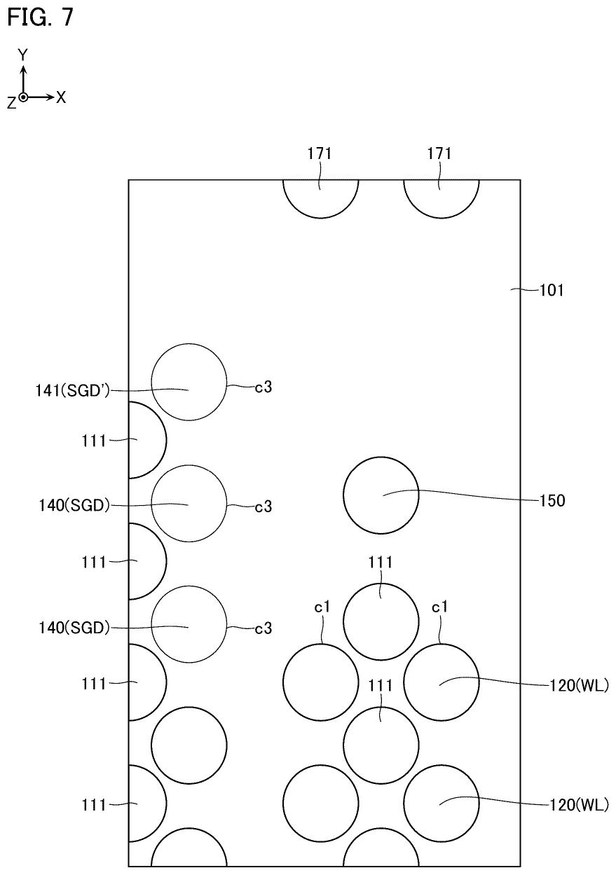

FIG. 3 is a schematic plan view showing a configuration of a part of the memory cell array layer L_{MCB}. FIGS. 4 and 5 are schematic cross-sectional views showing a configuration of a part of the memory cell array layer L_{MCB}. FIG. 4 shows a diagram in which the structure shown in FIG. 3 has been cut along the line A-A′ and viewed along a direction of the arrows. FIG. 5 shows a diagram in which the structure shown in FIG. 3 has been cut along the lines B-B′ and C-C′ and viewed along directions of the arrows. FIGS. 6 and 7 are schematic plan views showing a configuration of a part of the memory cell array layer L_{MCB}. FIG. 6 shows an XY cross section at a height position corresponding to the memory layer ML. FIG. 7 shows an XY cross section at a height position corresponding to the insulating layer 101.

As shown in FIG. 3, the memory cell array layer L_{MCA} comprises a bit line region R_{BL}, a select transistor region R_{SGD}, a memory cell region R_{MC}, a select transistor region R_{SGS}, and a source line region R_{SL} arranged in order in the Y-direction.

The memory layer ML comprises a plurality of semiconductor layers 110 arranged in the X-direction and extending in the Y-direction. These plurality of semiconductor layers 110 each extend in the Y-direction over the select transistor region R_{SGD}, the memory cell region R_{MC}, the select transistor region F_{SGS}, and the source line region R_{SL}, and reach the bit line region R_{BL}. The semiconductor layer 110 functions as channel regions of the serially-connected plurality of memory cells MC (FIG. 2) and of the select transistors STD, STS connected to these serially-connected plurality of memory cells MC, for example. The semiconductor layer 110 may include the likes of non-doped polycrystalline silicon (Si), for example.

An insulating layer 111 is provided between two semiconductor layers 110 arranged in the X-direction. The insulating layer 111 may include the likes of silicon oxide (SiO₂), for example. The insulating layer 111 extends in the Z-direction penetrating the plurality of memory layers ML, as shown in FIG. 1, for example.

The memory cell region R_{MC} is provided with a plurality of via electrodes 120 arranged in the Y-direction along side surfaces on one side and the other side in the X-direction of the semiconductor layer 110. In the example illustrated, the plurality of via electrodes 120 are arranged in the Y-direction at a pitch p1 on the one side and the other side in the X-direction of the semiconductor layer 110. Moreover, in the memory cell region R_{MC}, the memory layer ML comprises a plurality of gate insulating layers 130 provided between the plurality of via electrodes 120 and the semiconductor layer 110.

In the XY cross section of the kind exemplified in FIG. 6, a part of an outer peripheral surface of the via electrode 120 faces the semiconductor layer 110 via the gate insulating layer 130, and the remaining part of the outer peripheral surface of the via electrode 120 faces the insulating layer 111. The outer peripheral surface of the via electrode 120 lies along a circle c1 concentric with the via electrode 120. A contact surface with the semiconductor layer 110 of the gate insulating layer 130 lies along a circle c2 concentric with the circle c1. A radius of the circle c2 is larger than a radius of the circle c1. Note that the outer peripheral surface of the via electrode 120 lies along the circle c1 in the XY cross section of the kind exemplified in FIG. 7, too.

The via electrode 120 functions as the gate electrodes of a plurality of the memory cells MC, and as the word line WL connected to the gate electrodes of the plurality of the memory cells MC, for example. The via electrode 120 may include a barrier conductive layer of the likes of titanium nitride (TiN), and a conductive layer of the likes of tungsten (W), for example. The via electrode 120 extends in the Z-direction penetrating the plurality of memory layers ML, as shown in FIG. 1, for example.

As shown in FIG. 4, the gate insulating layer 130 comprises, for example: a tunnel insulating layer 131 provided on a side surface in the X-direction of the semiconductor layer 110; an electric charge accumulating layer 132 provided on a side surface in the X-direction of the tunnel insulating layer 131; and a block insulating layer 133 provided on a side surface in the X-direction of the electric charge accumulating layer 132.

The tunnel insulating layer 131 may include the likes of silicon oxide (SiO₂), for example.

The electric charge accumulating layer 132 may include the likes of polycrystalline silicon (Si), for example. Moreover, this polycrystalline silicon (Si) may include an N-type impurity such as phosphorus (P) or P-type impurity such as boron (B), but need not include these impurities.

The block insulating layer 133 may include the likes of silicon oxide (SiO₂), for example. Moreover, the block insulating layer 133 may include an insulating metal oxide film (a high-dielectric constant insulating film) of aluminum oxide (AlO), hafnium oxide (HfO), or the like.

The select transistor region R_{SGD} (FIG. 3) is provided with: a plurality of via electrodes 140 and a via electrode 141 that are arranged in the Y-direction along a side surface on one side in the X-direction of the semiconductor layer 110; and a via wiring 150 provided on an opposite side of a center line CL to these plurality of via electrodes 140 and via electrode 141. Moreover, in the select transistor region R_{SGD}, the memory layer ML comprises a semiconductor layer 160 connected to one ends in the Y-direction of the plurality of semiconductor layers 110.

Note that the center line CL referred to here is a center line of the semiconductor layer 110 in an XY cross section. The center line CL is an imaginary straight line extending in the Y-direction. It is possible for a position in the X-direction of the center line CL to be stipulated by a mean value of a mean value of center positions in the X-direction of a plurality of the via electrodes 120 facing a side surface on one side in the X-direction of the semiconductor layer 110, and mean value of center positions in the X-direction of a plurality of the via electrodes 120 facing a side surface on the other side in the X-direction of the semiconductor layer 110, for example.

In the XY cross section of the kind exemplified in FIG. 6, a part of an outer peripheral surface of the via electrodes 140, 141 faces the semiconductor layer 110, and the remaining part of the outer peripheral surface of the via electrodes 140, 141 faces the insulating layer 111. A surface facing the semiconductor layer 110 of the via electrodes 140, 141 lies along a circle c4. A surface facing the insulating layer 111 of the via electrodes 140, 141 lies along a circle c3 concentric with the circle c4. A radius of the circle c4 is larger than a radius of the circle c3.

Note that the outer peripheral surface of the via electrodes 140, 141 lies along the circle c3 in the XY cross section of the kind exemplified in FIG. 7, too. In the XY cross section of the kind exemplified in FIG. 7, the circle c3 is concentric with the via electrodes 140, 141. The radius of the circle c3 may substantially match the radius of the circle c1. Moreover, the plurality of circles c1 and the plurality of circles c3 may be arranged in the Y-direction at the pitch p1, as shown in FIG. 3.

The via electrode 140 in the select transistor region R_{SGD} functions as the gate electrodes of a plurality of the drain side select transistors STD, and as the drain side select gate line SGD connected to the gate electrodes of the plurality of the drain side select transistors STD, for example. The via electrode 140 may include a barrier conductive layer of the likes of titanium nitride (TiN), and a conductive layer of the likes of tungsten (W), for example. The via electrode 140 extends in the Z-direction penetrating the plurality of memory layers ML, as shown in FIG. 5, for example. Moreover, the outer peripheral surface of the via electrode 140 is provided with an insulating layer 142 of the likes of silicon oxide (SiO₂) or aluminum oxide (Al₂O₃).

As shown in FIG. 3 or FIG. 6, the via electrode 141 is disposed between the plurality of via electrodes 140 and the semiconductor layer 160. The via electrode 141 is basically configured similarly to the via electrode 140. However, it is possible for the via electrode 141 to be applied with a different voltage from the via electrode 140.

The via wiring 150 functions as the likes of a contact wiring for supplying positive holes to the semiconductor layer 110, for example. The via wiring 150, for example, may include a semiconductor column of the likes of polycrystalline silicon (Si) including a P-type impurity such as boron (B), and formed in a circular column-like shape or cylindrical shape. Moreover, this semiconductor column may contact the plurality of semiconductor layers 110 stacked in the Z-direction. The via wiring 150 extends in the Z-direction penetrating the plurality of memory layers ML, as shown in FIG. 5, for example.

The semiconductor layer 160, for example, may include a semiconductor layer of the likes of polycrystalline silicon (Si) including an N-type impurity such as phosphorus (P), and may contact the semiconductor layer 110.

In the bit line region R_{BL} (FIG. 3), the memory layer ML comprises a conductive layer 170. Moreover, the bit line region R_{BL} is provided with a plurality of insulating layers 171 arranged in the X-direction along the conductive layer 170.

The conductive layer 170 functions as the bit line BL (FIG. 2), for example. The conductive layer 170 may include the likes of titanium nitride (TiN), for example. The conductive layer 170 extends in the X-direction, and is electrically connected to the plurality of semiconductor layers 110, via the semiconductor layer 160.

The insulating layer 171 may include the likes of silicon oxide (SiO₂), for example. The insulating layer 171 extends in the Z-direction penetrating the plurality of memory layers ML.

The select transistor region R_{SGS} (FIG. 3) is provided with: a plurality of the via electrodes 140 arranged in the Y-direction along a side surface on one side in the X-direction of the semiconductor layer 110; and the via wiring 150 provided on an opposite side of the center line CL to the plurality of via electrodes 140.

The via electrode 140 in the select transistor region R_{SGS} functions as the gate electrodes of a plurality of the source side select transistors STS, and as the source side select gate line SGS connected to the gate electrodes of the plurality of source side select transistors STS, for example.

The source line region R_{SL} is provided with a via wiring 180.

The via wiring 180 functions as the source line SL, for example. The via wiring 180, for example, may include the likes of polycrystalline silicon (Si) including an N-type impurity such as phosphorus (P), and may include a semiconductor column formed in a circular column-like shape or cylindrical shape. Moreover, this semiconductor column may contact a plurality of the semiconductor layers 110 stacked in the Z-direction. The via wiring 180 extends in the Z-direction penetrating the plurality of memory layers ML.

### [Write Operation]

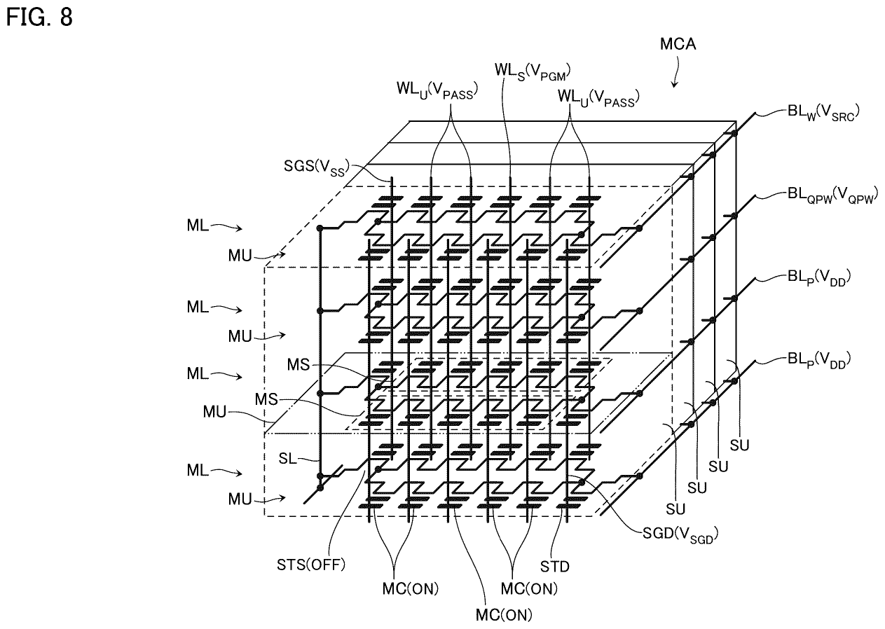

FIG. 8 is a schematic circuit diagram for explaining a write operation of the semiconductor memory device according to the present embodiment.

In the write operation, the plurality of memory cells MC connected to a single word line WL, in one string unit SU, represent selected memory cells MC. Hereafter, such a single word line WL will sometimes be referred to as a “selected word line WL_{S}”, and the remaining word lines WL will sometimes be referred to as “unselected word lines WL_{U}”.

In the write operation, for example, in a part of the plurality of selected memory cells MC, an electric field will be generated between their gate electrode and channel, and electrons in the channel of the semiconductor layer 110 will tunnel into their electric charge accumulating layer 132 (FIG. 4), thereby increasing threshold voltages of the part of the selected memory cells MC.

Hereafter, a selected memory cell MC whose threshold voltage is separated from its target value by a certain amount or more, of the selected memory cells MC, will be referred to as a “write memory cell MC”. Moreover, a bit line BL connected to a write memory cell MC will be referred to as a bit line BL_{W}. Moreover, a selected memory cell MC whose threshold voltage is to a certain extent close to its target value, of the selected memory cells MC, will be referred to as a “weak write memory cell MC”. Moreover, a bit line BL connected to a weak write memory cell MC will be referred to as a bit line BL_{QPW}.

Note that in the write operation, threshold voltages of only a part of the plurality of selected memory cells MC are increased, while threshold voltages of the remaining selected memory cells MC are not increased. Hereafter, this kind of selected memory cell MC whose threshold voltage is not to be increased, will be referred to as a “prohibit memory cell MC”. Moreover, a bit line BL connected to a prohibit memory cell MC will be referred to as a bit line BL_{P}.

In the write operation, for example, the bit line BL_{W} is applied with a voltage V_{SRC}. Moreover, the bit line BL_{QPW} is applied with a voltage V_{QPW}. Moreover, the bit line BL_{P} is applied with a voltage V_{DD}. Voltage V_{DD} is larger than voltages V_{SRC}, V_{QPW}. Voltage V_{QPW} is larger than voltage V_{SRC}, but smaller than voltage V_{DD}.

Moreover, in the write operation, the drain side select gate line SGD corresponding to the string unit SU representing a target of the write operation is applied with a voltage VSG_{D}, and other drain side select gate lines SGD are applied with a voltage Vo_{ET}.

Voltage V_{SGD} is larger than voltages V_{SRC}, V_{QPW}. Moreover, a voltage difference between the voltage V_{SGD} and the voltage V_{SRC} is larger than threshold voltage when the drain side select transistor STD is operated as an NMOS transistor. Similarly, a voltage difference between the voltage V_{SGD} and the voltage V_{QPW} is larger than such a threshold voltage. Hence, channels of electrons are formed in channel regions of the drain side select transistors STD connected to the bit lines BL_{W}, BL_{QPW}, and the voltages V_{SRC}, V_{QPW} are transferred to those channel regions of the drain side select transistors STD.

On the other hand, a voltage difference between the voltage V_{SGD} and the voltage V_{DD} is smaller than threshold voltage when the drain side select transistor STD is operated as an NMOS transistor. Hence, the drain side select transistor STD connected to the bit line BL_{P} will be in an OFF state.

Voltage V_{OFF} has a magnitude such that the drain side select transistor STD will be in an OFF state, regardless of voltage of the bit line BL. Voltage V_{OFF} may have a negative magnitude, for example.

Moreover, in the write operation, the source line SL is applied with the voltage V_{SRC}, and the source side select gate line SGS is applied with a ground voltage V_{SS}. Now, a voltage difference between the voltage V_{SRC} and the ground voltage V_{SS} is smaller than threshold voltage when the source side select transistor STS is operated as an NMOS transistor. Hence, the source side select transistor STS will be in an OFF state.

Moreover, in the write operation, the unselected word lines WL_{U} are applied with a write pass voltage V_{PASS}. A voltage difference between the write pass voltage V_{PASS} and the voltage V_{SRC} is larger than threshold voltage when the memory cell MC is operated as an NMOS transistor, regardless of data stored in the memory cell MC. Similarly, a voltage difference between the write pass voltage V_{PASS} and the voltage V_{QPW} is larger than such a threshold voltage regardless of data stored in the memory cell MC. Hence, channels of electrons are formed in channel regions of unselected memory cells MC electrically connected to the bit lines BL_{W}, BL_{QPW}, and the voltage V_{SRC} is transferred to the write memory cell MC, and the voltage V_{QPW} is transferred to the weak write memory cell MC.

Moreover, in the write operation, the selected word line WL_{S} is applied with a program voltage V_{PGM}. The program voltage V_{PGM} is larger than the write pass voltage V_{PASS}.

Now, the channel of the semiconductor layer 110 connected to the bit line BL_{W} is applied with the voltage V_{SRC}. Between such a semiconductor layer 110 and the selected word line WL_{S}, there will be generated a comparatively large electric field. This will cause electrons in the channel of the semiconductor layer 110 to tunnel into the electric charge accumulating layer 132 (FIG. 4) via the tunnel insulating layer 131 (FIG. 4). As a result, a comparatively large increase in threshold voltage of the write memory cell MC occurs.

Moreover, the channel of the semiconductor layer 110 connected to the bit line BL_{QPW} is applied with the voltage V_{QPW}. Between such a semiconductor layer 110 and the selected word line WL_{S}, there will be generated a smaller electric field than the above-described electric field. This will cause electrons in the channel of the semiconductor layer 110 to tunnel into the electric charge accumulating layer 132 (FIG. 4) via the tunnel insulating layer 131 (FIG. 4). As a result, a comparatively small increase in threshold voltage of the weak write memory cell MC occurs.

Moreover, the channel of the semiconductor layer 110 connected to the bit line BL_{P} is in an electrically floating state, and a potential of this channel rises to about the write pass voltage V_{PASS}, due to capacitive coupling with the unselected word lines WL_{U}. Between such a semiconductor layer 110 and the selected word line WL_{S}, there will only be generated a smaller electric field than the above-mentioned electric fields. Consequently, electrons in the channel of the semiconductor layer 110 will not tunnel into the electric charge accumulating layer 132 (FIG. 4). As a result, threshold voltage of the prohibit memory cell MC does not increase.

### [Interference Between Memory Layers ML in Write Operation]

In a semiconductor memory device of the kind described above, the via electrode 120 functioning as the gate electrode of the memory cell MC, and the via electrode 140 functioning as the gate electrode of the select transistor, are provided along a side surface in the X-direction of the semiconductor layer 110. Hence, during a read operation, a write operation, and so on, a channel (inversion layer) will be formed mainly in the side surface in the X-direction of the semiconductor layer 110.

Now, in a region whose distance from the via electrodes 120, 140 is comparatively far in the semiconductor layer 110, effects of electric fields from the via electrodes 120, 140 are comparatively small. On the other hand, there is a tendency for effects of an electric field from the semiconductor layer 110 in another memory layer ML adjacent in the Z-direction to be comparatively strong.

For example, in the write operation, in the case where one of two memory layers ML adjacent in the Z-direction corresponds to the bit line BL_{W} and the other of the two memory layers ML adjacent in the Z-direction corresponds to the bit line BL_{QPW}, there is a risk that, due to effects of an electric field from the semiconductor layer 110 corresponding to the bit line BL_{W}, it will become difficult for a channel (inversion layer) to be formed in the semiconductor layer 110 corresponding to the bit line BL_{QPW}, and it will become difficult for the drain side select transistor STD to be set to ON. There is hence a risk that it will become impossible for threshold voltage of the weak write memory cell MC to be adjusted.

Moreover, for example, in the case where one of two memory layers ML adjacent in the Z-direction corresponds to the bit line BL_{W} and the other of the two memory layers ML adjacent in the Z-direction corresponds to the bit line BL_{P}, focusing on an unselected string unit SU, there is a risk that a region whose distance from the via electrode 140 is comparatively far in the semiconductor layer 110 corresponding to the bit line BL_{P}, will be applied with the voltage V_{DD}. Moreover, there is a risk that, due to effects of an electric field from this semiconductor layer 110, a channel (inversion layer) will be formed in the semiconductor layer 110 corresponding to the bit line BL_{W}, and an OFF leak current will be generated in the drain side select transistor STD. There is hence a risk that a miswrite will occur in a string unit SU which is not a target of operation.

Now, for example, in order for the drain side select transistor STD to be surely set to an ON state, it is conceivable for pitch in the Y-direction at which the via electrodes 140 are disposed to be reduced, or area in an XY cross section of the via electrode 140 to be increased, and for a distance between the via electrodes 140 and a distance between the via electrode 140 and the gate insulating layer 130 to be thereby reduced, for example. However, sometimes, restrictions are set on position and size of the via electrode 140, in relation to a manufacturing method of the semiconductor memory device.

Accordingly, in the present embodiment, when manufacturing the semiconductor memory device, a part of the semiconductor layer 110 is removed after formation of a via hole corresponding to the via electrode 140, and a part of the via electrode 140 is formed in this removed part. As a result, the radius of the circle c4 corresponding to a surface facing the semiconductor layer 110 of the via electrode 140 will be larger than the radius of the circle c3 corresponding to a surface facing the insulating layer 111 of the via electrode 140.

Such a configuration makes it possible for the distance between the via electrodes 140 and the distance between the via electrode 140 and the gate insulating layer 130 to be reduced, and for it to be thereby made easier for an electric field to be delivered to the entire side surface in the X-direction of the semiconductor layer 110. Hence, even in the case where one of two memory layers ML adjacent in the Z-direction corresponds to the bit line BL_{W} and the other of the two memory layers ML adjacent in the Z-direction corresponds to the bit line BL_{QPW}, it is possible for the drain side select transistor STD corresponding to the bit line BL_{QP}W to be suitably set to an ON state.

Moreover, in the present embodiment, the select transistor region R_{SGD} is provided with the via wiring 150. Such a configuration makes it possible for a voltage of a region whose distance from the via electrodes 120, 140 is comparatively far in the semiconductor layer 110, to be fixed via the via wiring 150. It is hence possible to suppress that a region whose distance from the via electrode 140 is comparatively far in the semiconductor layer 110 corresponding to the bit line BL_{P}, will be applied with the voltage V_{DD}. This makes it possible for occurrence of miswrite to be suppressed.

### [Interference of GIDL Current in Write Operation]

As mentioned above, in the write operation, in a string unit SU which is not a target of operation, the drain side select gate line SGD (via electrode 140) is applied with the voltage Von, whereby the drain side select transistor STD is set to an OFF state.

Now, as shown in FIGS. 3 and 6, for example, the via electrode 141 is sometimes closely adjacent to the semiconductor layer 160. When, for example, the semiconductor layer 160 corresponding to the bit line BL_{P} is applied with voltage V_{DD}, and the via electrode 141 is applied with voltage V_{OFF} having a negative magnitude, an electric field will sometimes concentrate between the semiconductor layer 160 and the via electrode 141. There is hence a risk of there being a steep change in energy band, whereby GIDL (Gate Induced Drain Leakage) occurs.

Accordingly, in the present embodiment, the via electrode 141 is configured capable of being applied with a different voltage from the via electrode 140. Moreover, in the write operation, the via electrode 141 is applied with a voltage between the voltage V_{DD} and the voltage V_{OFF}. Such a method enables occurrence of GIDL to be suppressed.

### Second Embodiment

In the via electrodes 140, 141 according to the first embodiment, the surface facing the semiconductor layer 110 lies along the circle c4, and the surface facing the insulating layer 111 lies along the circle c3. However, such a configuration is merely an exemplification, and specific configuration can be appropriately adjusted.

For example, when manufacturing the semiconductor memory device, a part of the insulating layer 111, rather than the semiconductor layer 110, may be removed after formation of the via hole corresponding to the via electrode 140. In such a case, a radius of a circle corresponding to the surface facing the insulating layer 111 of the via electrode 140 will be larger than a radius of a circle corresponding to the surface facing the semiconductor layer 110 of the via electrode 140.

Such an example will be described below as a semiconductor memory device according to a second embodiment.

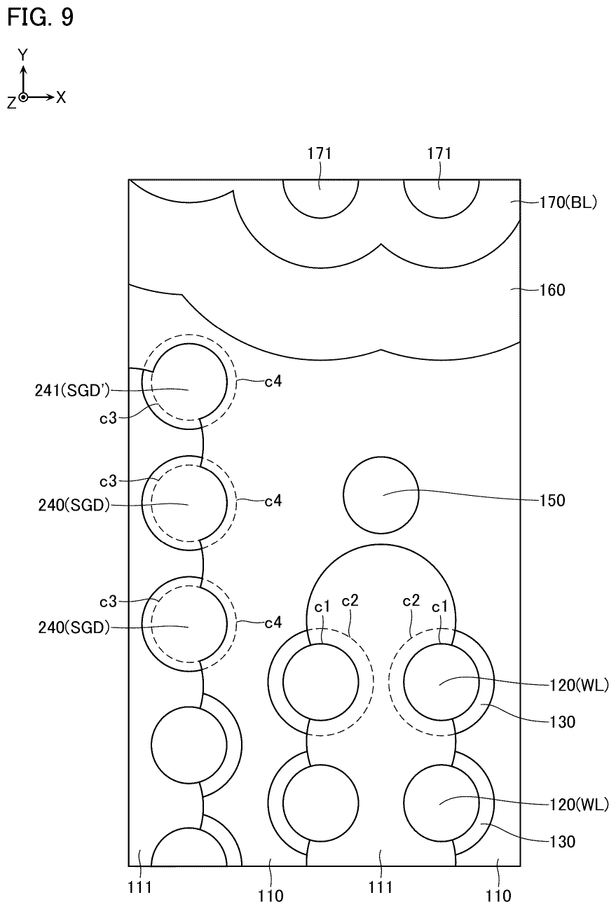

FIG. 9 is a schematic plan view showing a configuration of a part of the semiconductor memory device according to the second embodiment. In the following description, portions similar to in the first embodiment will be assigned with the same symbols as in the first embodiment, and descriptions thereof omitted.

The semiconductor memory device according to the second embodiment is basically configured similarly to the semiconductor memory device according to the first embodiment. However, the semiconductor memory device according to the second embodiment comprises via electrodes 240, 241 instead of the via electrodes 140, 141.

The via electrodes 240, 241 are basically configured similarly to the via electrodes 140, 141. However, the surface facing the semiconductor layer 110 of the via electrodes 240, 241 lies along the circle c3. Moreover, the surface facing the insulating layer 111 of the via electrodes 240, 241 lies along the circle c4.

Such a configuration, too, makes it possible for a distance between the via electrodes 240 and a distance between the via electrode 240 and the gate insulating layer 130 to be reduced, and for it to be thereby made easier for an electric field to be delivered to the entire side surface in the X-direction of the semiconductor layer 110, similarly to in the first embodiment.

Note that in the case where the insulating layer 111 and the insulating layer 101 include the same material, there is a possibility that when a part of the insulating layer 111 is removed after formation of a via hole corresponding to the via electrodes 240, 241, the insulating layer 101 will also be simultaneously removed. In such a case, an outer peripheral surface of the via electrodes 240, 241 may lie along the circle c4 in an XY cross section of the kind corresponding to FIG. 7.

### Third Embodiment

When manufacturing the semiconductor memory device according to the first embodiment, a part of the semiconductor layer 110 is removed after formation of the via hole corresponding to the via electrodes 140, 141. Moreover, when manufacturing the semiconductor memory device according to the second embodiment, a part of the insulating layer 111 is removed after formation of the via hole corresponding to the via electrodes 240, 241. However, such configurations are merely exemplifications, and specific configuration may be appropriately adjusted.

For example, when manufacturing the semiconductor memory device, both part of the semiconductor layer 110 and part of the insulating layer 111 may be removed after formation of the via hole corresponding to the via electrodes 140, 141. For example, in the case where the radius of the circle c3 substantially matches the radius of the circle c1, both radius of a circle corresponding to the surface facing the semiconductor layer 110 and radius of a circle corresponding to the surface facing the insulating layer 111, of the via electrodes 140, 141, will be larger than the radius of the circle c1.

Such an example will be described below as a semiconductor memory device according to a third embodiment.

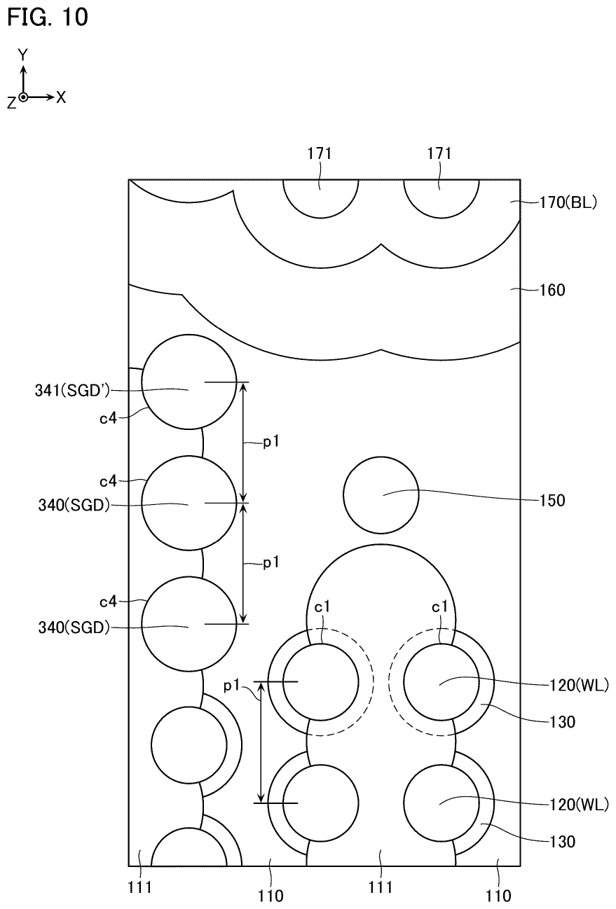

FIG. 10 is a schematic plan view showing a configuration of a part of the semiconductor memory device according to the third embodiment. In the following description, portions similar to in the first embodiment will be assigned with the same symbols as in the first embodiment, and descriptions thereof omitted.

The semiconductor memory device according to the third embodiment is basically configured similarly to the semiconductor memory device according to the first embodiment. However, the semiconductor memory device according to the third embodiment comprises via electrodes 340, 341 instead of the via electrodes 140, 141.

The via electrodes 340, 341 are basically configured similarly to the via electrodes 140, 141. However, the surface facing the semiconductor layer 110 of the via electrodes 340, 341 lies along the circle c4. Moreover, the surface facing the insulating layer 111 of the via electrodes 340, 341 also lies along the circle c4.

Such a configuration, too, makes it possible for a distance in the Y-direction between the via electrodes 340 and a distance in the Y-direction between the via electrode 340 and the gate insulating layer 130 to be reduced, and for it to be thereby made easier for an electric field to be delivered to the entire side surface in the X-direction of the semiconductor layer 110, similarly to in the first embodiment.

Note that the surface facing the semiconductor layer 110 and surface facing the insulating layer 111, of the via electrodes 340, 341 may lie along circles having different radii. Moreover, the surface facing the insulating layer 111 of the via electrodes 340, 341 may lie along a circle corresponding to an outer peripheral surface of the via electrodes 340, 341 in an XY cross section of the kind corresponding to FIG. 7.

### Fourth Embodiment

In the first through third embodiments, the via electrodes 140, 141, the via electrodes 240, 241, or the via electrodes 340, 341 (hereafter, called “via electrodes 140, and so on”) are arranged in the Y-direction at the same pitch p1 as the via electrodes 120. However, such configurations are merely exemplifications, and specific configuration may be appropriately adjusted.

For example, the via electrodes 140, and so on, may be arranged in the Y-direction at a smaller pitch than pitch p1. Such a configuration makes it possible for a distance in the Y-direction between the via electrodes 140, and so on, and a distance in the Y-direction between the via electrode 140, and so on, and the gate insulating layer 130 to be reduced, and for it to be thereby made easier for an electric field to be delivered to the entire side surface in the X-direction of the semiconductor layer 110, without a part of the semiconductor layer 110 and/or a part of the insulating layer 111 being removed after formation of the via hole corresponding to the via electrodes 140, and so on.

Such an example will be described below as a semiconductor memory device according to a fourth embodiment.

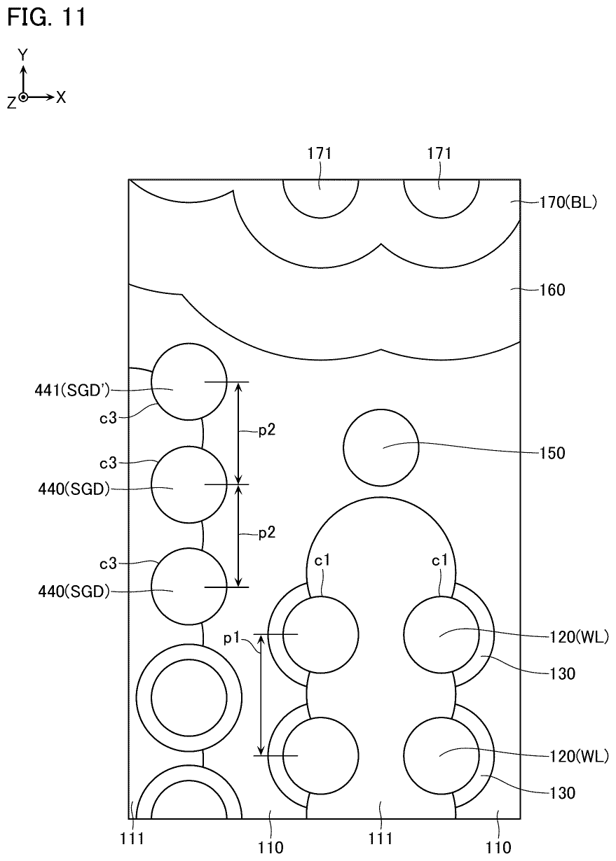

FIG. 11 is a schematic plan view showing a configuration of a part of the semiconductor memory device according to the fourth embodiment. In the following description, portions similar to in the first embodiment will be assigned with the same symbols as in the first embodiment, and descriptions thereof omitted.

The semiconductor memory device according to the fourth embodiment is basically configured similarly to the semiconductor memory device according to the first embodiment. However, the semiconductor memory device according to the fourth embodiment comprises via electrodes 440, 441 instead of the via electrodes 140, 141.

The via electrodes 440, 441 are basically configured similarly to the via electrodes 140, 141. However, both a surface facing the semiconductor layer 110 and a surface facing the insulating layer 111, of the via electrodes 440, 441 lie along the circle c3. Moreover, in the present embodiment, the circles c3 corresponding to these plurality of via electrodes 440, 441 are arranged in the Y-direction at a pitch p2 smaller than pitch p1.

### Fifth Embodiment

When manufacturing the semiconductor memory devices according to the first through fourth embodiments, a circular hole is formed as the via hole corresponding to the via electrodes 140, and so on. However, such configurations are merely exemplifications, and shape of the via hole corresponding to the via electrodes 140, and so on, is appropriately adjustable.

For example, shape of the via hole corresponding to the via electrodes 140, and so on, may be elliptical or rectangular-with-rounded-ends (racetrack shaped), or may be triangular, square, or another geometrical shape.

Such an example will be described below as a semiconductor memory device according to a fifth embodiment.

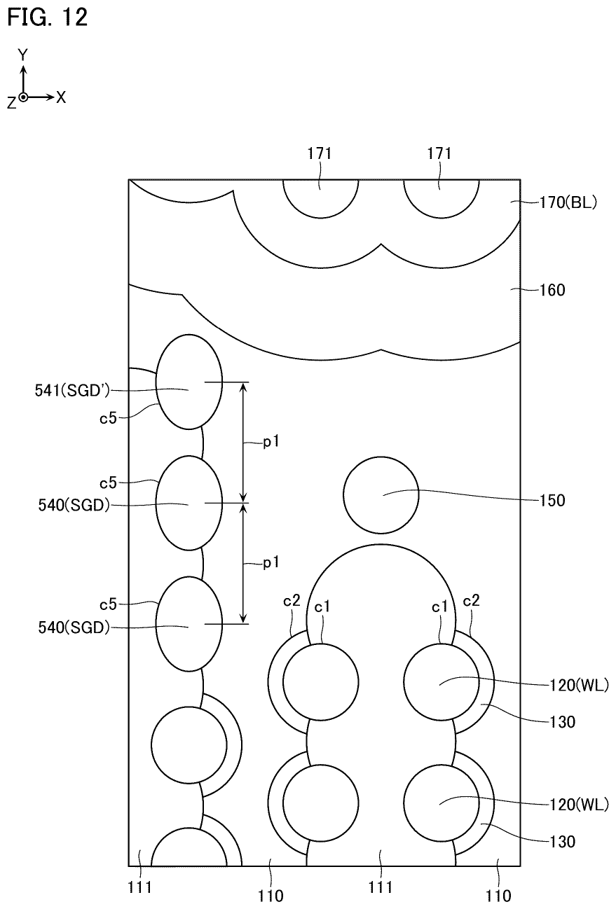

FIG. 12 is a schematic plan view showing a configuration of a part of the semiconductor memory device according to the fifth embodiment. In the following description, portions similar to in the first embodiment will be assigned with the same symbols as in the first embodiment, and descriptions thereof omitted.

The semiconductor memory device according to the fifth embodiment is basically configured similarly to the semiconductor memory device according to the first embodiment. However, the semiconductor memory device according to the fifth embodiment comprises via electrodes 540, 541 instead of the via electrodes 140, 141.

The via electrodes 540, 541 are basically configured similarly to the via electrodes 140, 141. However, both a surface facing the semiconductor layer 110 and a surface facing the insulating layer 111, of the via electrodes 540, 541 lie along an ellipse c5. In the example illustrated, a major axis of the ellipse c5 extends in the Y-direction. Moreover, a minor axis of the ellipse c5 extends in the X-direction. Note that in the example illustrated, size of the minor axis of the ellipse c5 substantially matches diameter of the circle c1.

Such a configuration, too, makes it possible for a distance in the Y-direction between the via electrodes 540 and a distance in the Y-direction between the via electrode 540 and the gate insulating layer 130 to be reduced, and for it to be thereby made easier for an electric field to be delivered to the entire side surface in the X-direction of the semiconductor layer 110, similarly to in the first embodiment.

### Sixth Embodiment

In the semiconductor memory devices according to the first through fifth embodiments, in the select transistor region R_{SD}, the via electrodes 140, and so on, are provided only on one side in the X-direction of the semiconductor layer 110, while on the other side in the X-direction of the semiconductor layer 110, the via electrodes 140, and so on, are not provided. However, such configurations are merely exemplifications, and arrangement of the via electrodes 140, and so on, is appropriately adjustable.

For example, the via electrodes 140, and so on, may be provided not only on one side in the X-direction of the semiconductor layer 110, but also on the other side in the X-direction of the semiconductor layer 110.

Such an example will be described below as a semiconductor memory device according to a sixth embodiment.

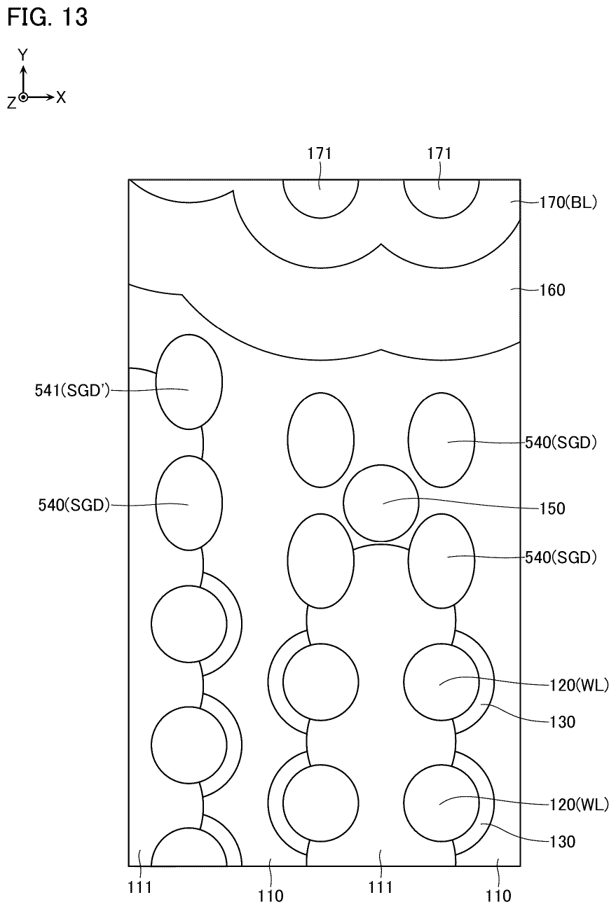

FIG. 13 is a schematic plan view showing a configuration of a part of the semiconductor memory device according to the sixth embodiment. In the following description, portions similar to in the fifth embodiment will be assigned with the same symbols as in the fifth embodiment, and descriptions thereof omitted.

The semiconductor memory device according to the sixth embodiment is basically configured similarly to the semiconductor memory device according to the fifth embodiment. However, in the semiconductor memory device according to the sixth embodiment, the via electrode 540 is provided not only on one side in the X-direction of the semiconductor layer 110, but also on the other side in the X-direction of the semiconductor layer 110.

Such a configuration, too, makes it possible for a distance in the Y-direction between the via electrodes 540 and a distance in the Y-direction between the via electrode 540 and the gate insulating layer 130 to be reduced, and for it to be thereby made easier for an electric field to be delivered to the entire side surface in the X-direction of the semiconductor layer 110, similarly to in the first embodiment.

### Seventh Embodiment

The semiconductor memory devices according to the fifth and sixth embodiments comprise the via electrodes 540, 541 having a shape lying along the ellipse c5. Now, in the fifth and sixth embodiments, the major axis of the ellipse c5 extends in the Y-direction. However, an angle in an XY cross section of the via electrodes 540, 541 is appropriately adjustable, too.

An example where the via electrodes 540, 541 are rotated in an XY cross section will be described below as a semiconductor memory device according to a seventh embodiment.

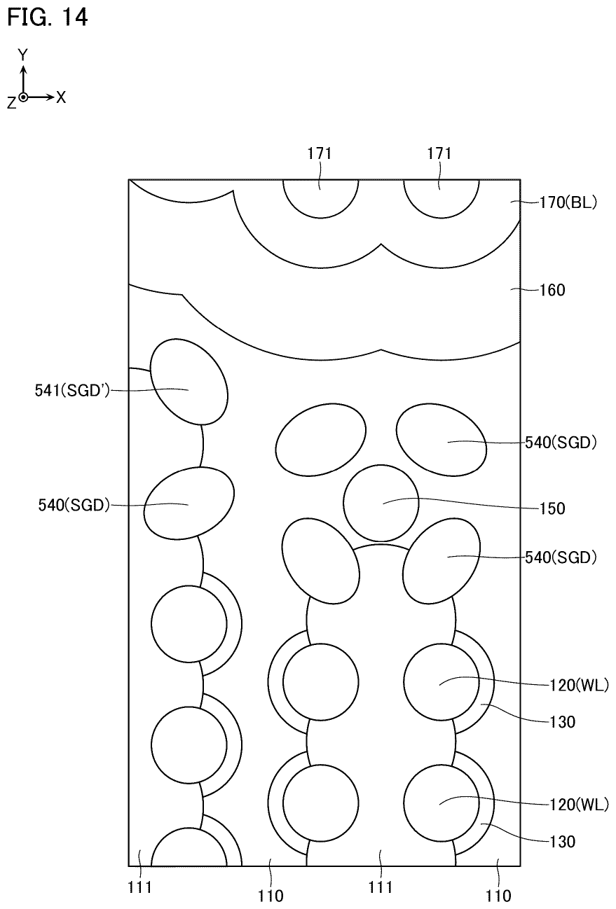

FIG. 14 is a schematic plan view showing a configuration of a part of the semiconductor memory device according to the seventh embodiment. In the following description, portions similar to in the sixth embodiment will be assigned with the same symbols as in the sixth embodiment, and descriptions thereof omitted.

The semiconductor memory device according to the seventh embodiment is basically configured similarly to the semiconductor memory device according to the sixth embodiment. However, in the semiconductor memory device according to the seventh embodiment, the major axis of the via electrodes 540, 541 extends along an oblique direction in an XY cross section. More specifically, the major axes of the via electrodes 540, 541 are disposed so as to intersect at a single point on the semiconductor layer 110.

Such a configuration, too, makes it possible for the distance in the Y-direction between the via electrodes 540 and the distance in the Y-direction between the via electrode 540 and the gate insulating layer 130 to be reduced, and for it to be thereby made easier for an electric field to be delivered to the entire side surface in the X-direction of the semiconductor layer 110, similarly to in the first embodiment.

### Eighth Embodiment

In the semiconductor memory devices according to the first through seventh embodiments, the select transistor region Rsc_{D} is provided with the via wiring 150. Such a configuration makes it possible for a voltage of a region whose distance from the via electrodes 140, and so on, is comparatively far in the semiconductor layer 110, to be fixed via the via wiring 150, and for occurrence of the above-mentioned kind of miswrite to be thereby suppressed. However, such miswrite can also be suppressed by another method.

For example, when the semiconductor layer 110 is provided within a certain range from the via electrodes 140, and so on, in the select transistor region R_{SGD}, the very region itself, that is, a region whose distance from the via electrodes 140, and so on, is comparatively far, will not exist, and it will hence be possible for the drain side select transistor STD to be suitably set to an OFF state, and for occurrence of the above-mentioned kind of miswrite to be thereby suppressed.

Such an example will be described below as a semiconductor memory device according to an eighth embodiment.

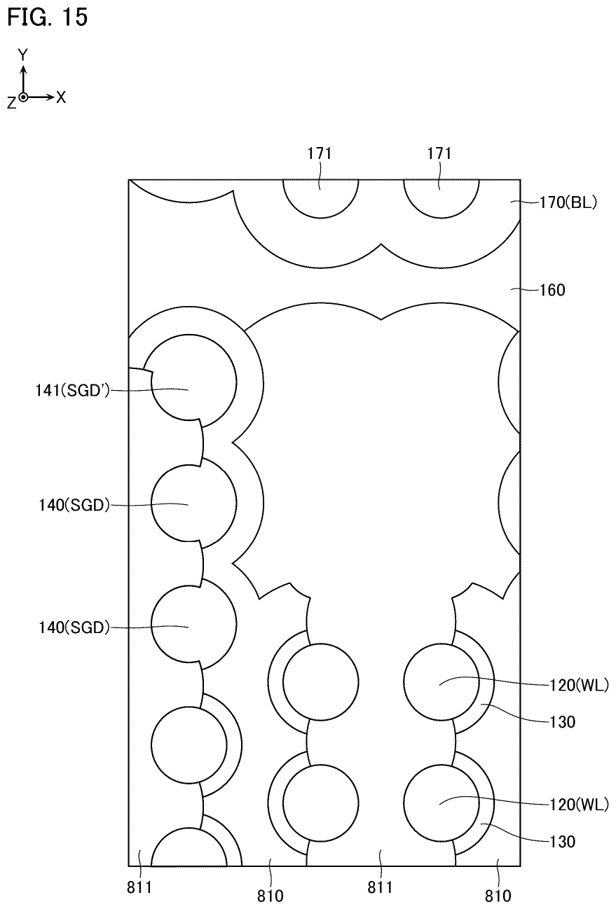

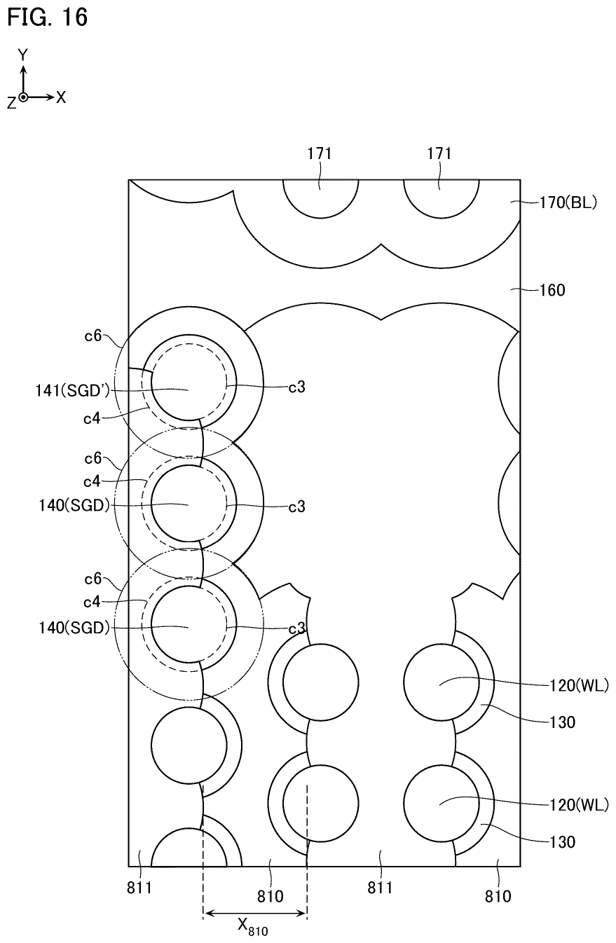

FIGS. 15 and 16 are schematic plan views showing a configuration of a part of the semiconductor memory device according to the eighth embodiment. In the following description, portions similar to in the first embodiment will be assigned with the same symbols as in the first embodiment, and descriptions thereof omitted.

The semiconductor memory device according to the eighth embodiment is basically configured similarly to the semiconductor memory device according to the first embodiment. However, the semiconductor memory device according to the eighth embodiment comprises a semiconductor layer 810 and an insulating layer 811, instead of the semiconductor layer 110 and the insulating layer 111. Moreover, the semiconductor memory device according to the eighth embodiment does not comprise the via wiring 150.

The semiconductor layer 810 and the insulating layer 811 are basically configured similarly to the semiconductor layer 110 and the insulating layer 111. However, the semiconductor layer 810 is provided within a certain range from the via electrodes 140, and so on, in the select transistor region R_{SGD}. That is, as shown in FIG. 16, for example, a side surface on an opposite side to the via electrodes 140 in the X-direction of the semiconductor layer 810 lies along a plurality of circles c6 concentric with pluralities of the circles c3, c4, in the select transistor region R_{SGD}. A radius of the circle c6 is larger than the radius of the circle c4, but smaller than width X₈₁₀ in the X-direction of the semiconductor layer 810 in the memory cell region R_{MC}. Moreover, a side surface on a via electrodes 140 side in the X-direction of the semiconductor layer 810 lies along the plurality of circles c4. Note that a region between two semiconductor layers 810 arranged in the X-direction is filled in by the insulating layer 811.

Such a configuration, too, makes it possible for occurrence of the above-mentioned kind of miswrite to be suppressed, similarly to in the first embodiment.

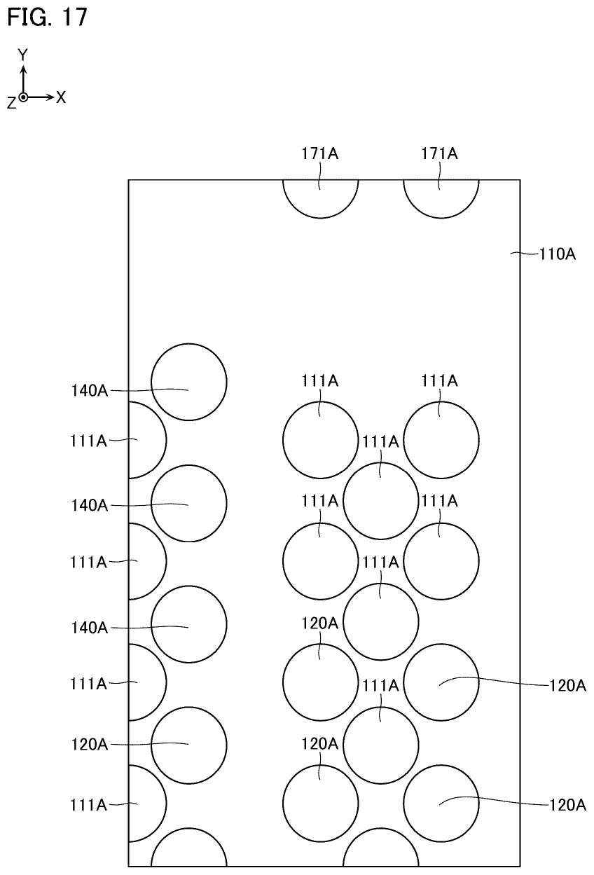

FIGS. 17 to 21 are schematic plan views for explaining a method of manufacturing the semiconductor memory device according to the eighth embodiment.

When manufacturing the semiconductor memory device according to the eighth embodiment, sacrifice layers 110A and the insulating layers 101 are stacked alternately in the Z-direction. The sacrifice layer 110A includes the likes of silicon nitride (SiN), for example. This step is performed by a method such as CVD (Chemical Vapor Deposition), for example.

Next, as shown in FIG. 17, for example, a plurality of openings that penetrate a plurality of the sacrifice layers 110A and a plurality of the insulating layers 101 stacked alternately in the Z-direction, are formed. Openings 111A are formed at positions corresponding to the insulating layers 111. Openings 120A are formed at positions corresponding to the via electrodes 120. Openings 140A are formed at positions corresponding to the via electrodes 140, 141. Openings 171A are formed at positions corresponding to the insulating layers 171. This step is performed by a method such as RIE (Reactive Ion Etching), for example. Note that insides of each of the openings are filled in by a sacrifice layer of silicon (Si), carbon (C), or the like.

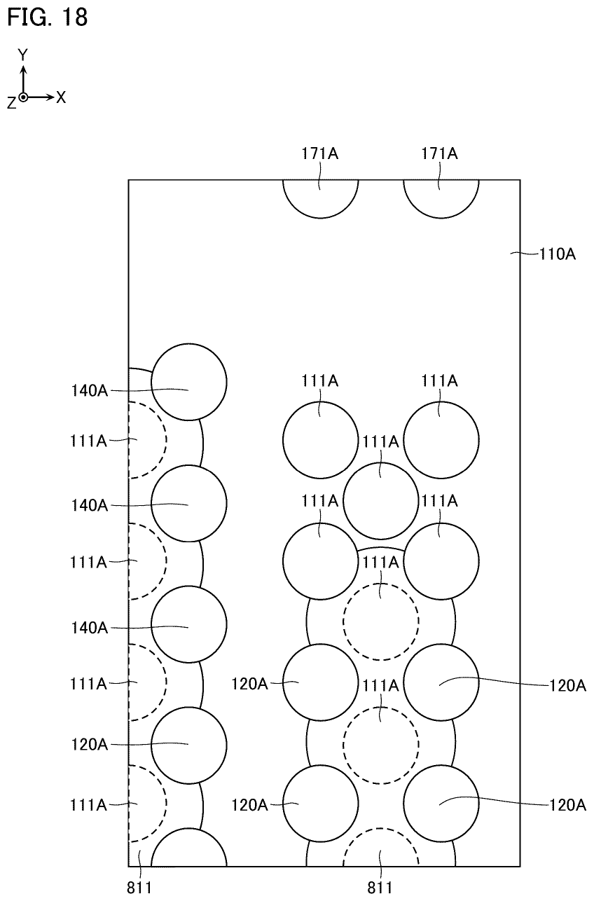

Next, as shown in FIG. 18, for example, the sacrifice layers on the insides of the openings 111A in the memory cell region F_{MC} are removed, parts of the sacrifice layers 110A are removed by a method such as wet etching via the openings 111A, and parts of the insulating layers 811 are formed by a method such as CVD.

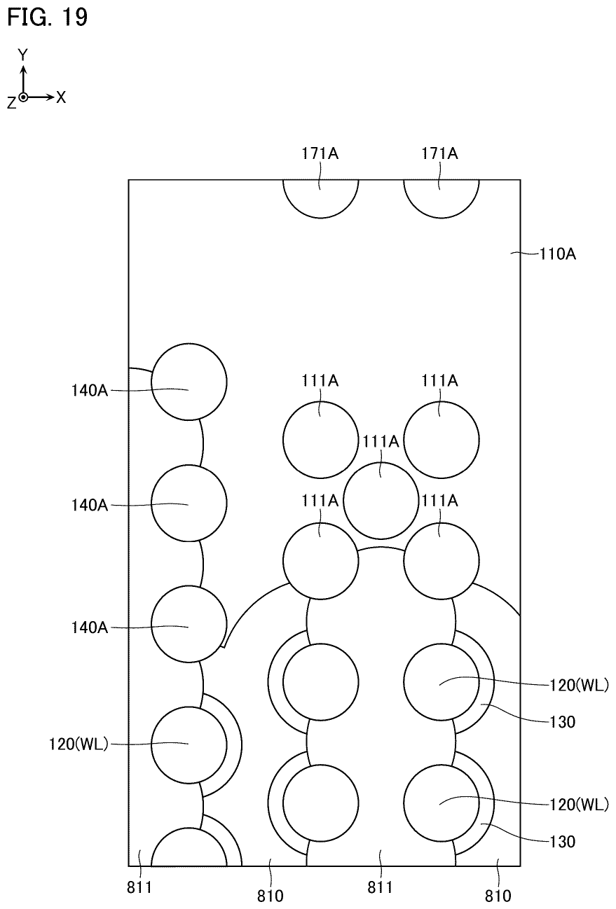

Next, as shown in FIG. 19, for example, the sacrifice layers on the insides of the openings 120A are removed, parts of the sacrifice layers 110A are removed by a method such as wet etching via the openings 120A, and part of the semiconductor layers 810 are formed by a method such as CVD. In addition, parts of the semiconductor layers 810 are removed by a method such as wet etching via the opening 120A, and the gate insulating layers 130 and the via electrodes 120 are formed by a method such as CVD.

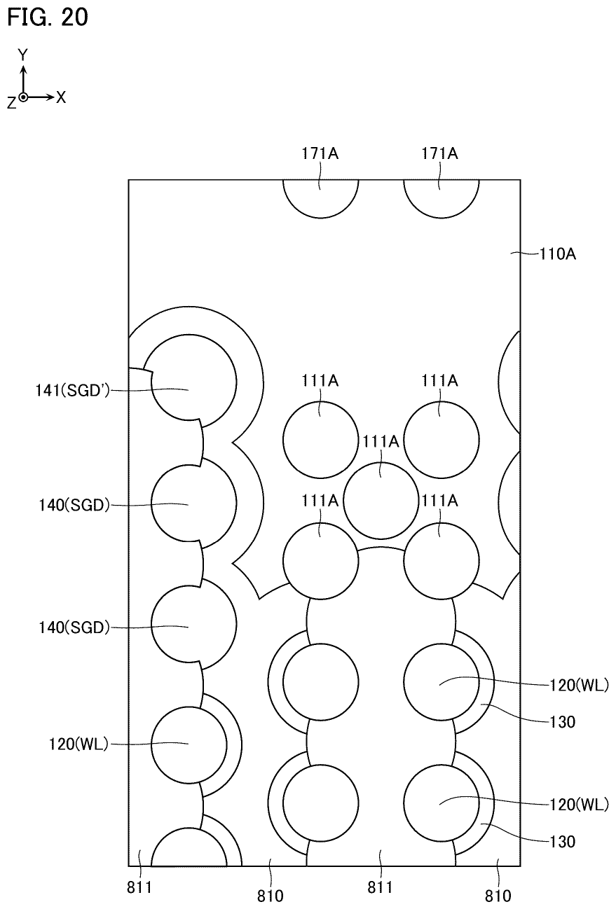

Next, as shown in FIG. 20, for example, the sacrifice layers on the insides of the openings 140A are removed, parts of the sacrifice layers 110A are removed by a method such as wet etching via the opening 140A, and parts of the semiconductor layers 810 are formed by a method such as CVD. Adjustment of etching amount at this timing enables channel width of the drain side select transistor STD according to the present embodiment to be adjusted. In addition, parts of the semiconductor layers 810 are removed by a method such as wet etching via the opening 140A, and the via electrodes 140, 141 are formed by a method such as CVD.

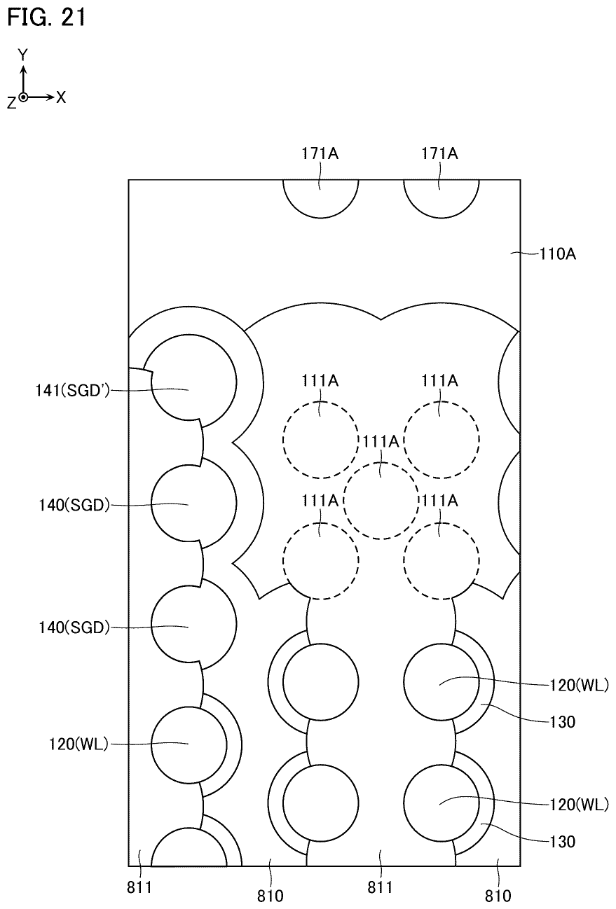

Next, as shown in FIG. 21, for example, the sacrifice layers on the insides of the openings 111A in the select transistor region R_{SGD} are removed, parts of the sacrifice layers 110A are removed by a method such as wet etching via the openings 111A, and parts of the insulating layer 811 are formed by a method such as CVD.

Next, for example, the sacrifice layers on the insides of the openings 171A are removed, the sacrifice layers 110A are removed by a method such as wet etching via the opening 171A, and the semiconductor layer 160, the conductive layer 170, and the insulating layer 171 are formed by a method such as CVD. As a result, a structure of the kind described with reference to FIG. 15 is formed.

### Ninth Embodiment

During manufacturing of the semiconductor memory device according to the eighth embodiment, in the step described with reference to FIG. 21, the openings 111A are filled in by a part of the insulating layer 811. However, such a method is merely an exemplification, and, in the step described with reference to FIG. 21, a via electrode may be formed in the opening 111A. Such a configuration makes it possible for an ON operation and OFF operation of the drain side select transistor STD to be more stably executed.

Such an example will be described below as a semiconductor memory device according to a ninth embodiment.

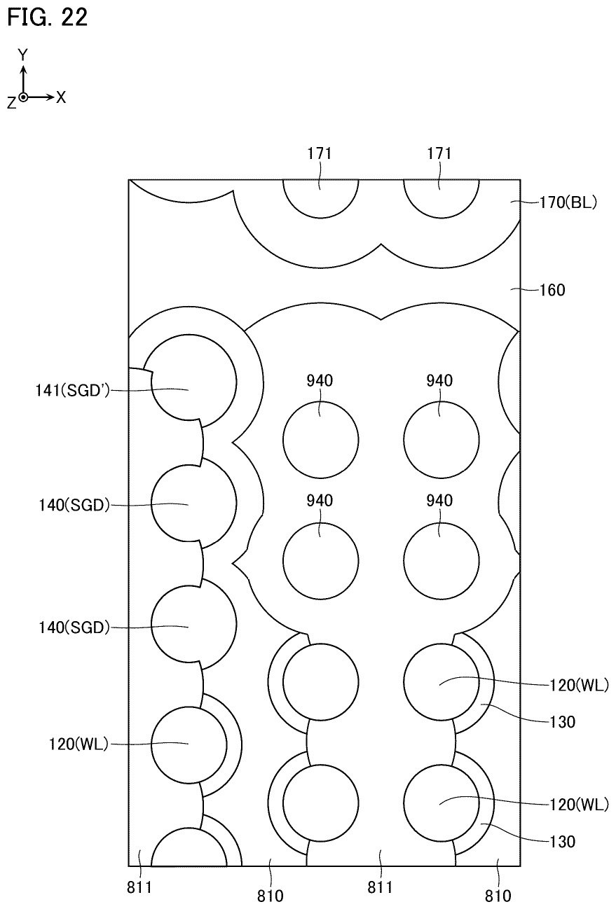

FIG. 22 is a schematic plan view showing a configuration of a part of the semiconductor memory device according to the ninth embodiment. In the following description, portions similar to in the eighth embodiment will be assigned with the same symbols as in the eighth embodiment, and descriptions thereof omitted.

The semiconductor memory device according to the ninth embodiment is basically configured similarly to the semiconductor memory device according to the eighth embodiment. However, in the semiconductor memory device according to the ninth embodiment, a via electrode 940 is provided on an opposite side to the via electrodes 140, 141 in the X-direction, in the select transistor region R_{SGD}. The via electrode 940 may be formed similarly to the via electrode 140, for example.

Such a configuration makes it possible for the drain side select transistor STD to be more suitably set to an ON state or OFF state.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a plurality of semiconductor layers and a plurality of insulating layers stacked alternately in a stacking direction and extending in a first direction intersecting the stacking direction;
a plurality of conductive layers which are stacked in the stacking direction correspondingly to the plurality of semiconductor layers, extend in a second direction intersecting the stacking direction and the first direction, and are connected to end portions in the first direction of the plurality of semiconductor layers;
a plurality of first via electrodes which are arranged in the first direction along side surfaces in the second direction of the plurality of semiconductor layers, extend in the stacking direction, and face the plurality of semiconductor layers;
a plurality of electric charge accumulating layers provided between the plurality of semiconductor layers and the plurality of first via electrodes; and
a plurality of second via electrodes which are provided between the plurality of conductive layers and the plurality of first via electrodes, are arranged in the first direction along side surfaces in the second direction of the plurality of semiconductor layers, extend in the stacking direction, and face the plurality of semiconductor layers, wherein
in a first cross section extending in the first direction and the second direction, and including one of the plurality of semiconductor layers,
a surface facing the one of the plurality of semiconductor layers, of the second via electrode lies along a first circle, and
a surface on an opposite side to the plurality of semiconductor layers, of the second via electrode lies along a second circle,
in a second cross section extending in the first direction and the second direction, and including one of the plurality of insulating layers, an outer peripheral surface of the second via electrode lies along a third circle, and
a radius of at least one of the first circle and the second circle differs from a radius of the third circle.

2. The semiconductor memory device according to claim 1, wherein
the radius of the first circle is larger than the radius of the third circle.

3. The semiconductor memory device according to claim 1, wherein
a radius of the first circle is smaller than a radius of the second circle.

4. The semiconductor memory device according to claim 1, wherein
the radius of the second circle matches the radius of the third circle.

5. The semiconductor memory device according to claim 1, wherein
in the second cross section, an outer peripheral surface of the first via electrode lies along a fourth circle, and
a radius of at least one of the first circle and the second circle is larger than a radius of the fourth circle.

6. The semiconductor memory device according to claim 1, wherein
the plurality of first via electrodes and the plurality of second via electrodes are arranged in the first direction at a constant pitch.

7. A semiconductor memory device comprising:
a plurality of semiconductor layers stacked in a stacking direction and extending in a first direction intersecting the stacking direction;
a plurality of conductive layers which are stacked in the stacking direction, extend in a second direction intersecting the stacking direction and the first direction, and are connected to end portions in the first direction of the plurality of semiconductor layers;
a plurality of first via electrodes which are arranged in the first direction along side surfaces in the second direction of the plurality of semiconductor layers, extend in the stacking direction, and face the plurality of semiconductor layers;
a plurality of charge accumulating layers provided between the plurality of semiconductor layers and the plurality of first via electrodes;
a plurality of second via electrodes which are provided between the plurality of conductive layers and the plurality of first via electrodes, are arranged in the first direction along side surfaces in the second direction of the plurality of semiconductor layers, extend in the stacking direction, and face the plurality of semiconductor layers; and
a semiconductor column which is provided on an opposite side to the plurality of second via electrodes with respect to a center position in the second direction of the plurality of semiconductor layers, extends in the stacking direction, and contacts the plurality of semiconductor layers.

8. The semiconductor memory device according to claim 7, wherein
the semiconductor column includes a P-type impurity.

9. A semiconductor memory device comprising:
a plurality of semiconductor layers stacked in a stacking direction and extending in a first direction intersecting the stacking direction;
a plurality of conductive layers which are stacked in the stacking direction, extend in a second direction intersecting the stacking direction and the first direction, and are connected to end portions in the first direction of the plurality of semiconductor layers;
a plurality of first via electrodes which are arranged in the first direction along side surfaces in the second direction of the plurality of semiconductor layers, extend in the stacking direction, and face the plurality of semiconductor layers;
a plurality of electric charge accumulating layers provided between the plurality of semiconductor layers and the plurality of first via electrodes;
a plurality of second via electrodes which are provided between the plurality of conductive layers and the plurality of first via electrodes, are arranged in the first direction along side surfaces in the second direction of the plurality of semiconductor layers, extend in the stacking direction, and face the plurality of semiconductor layers; and
a third via electrode which is provided between the plurality of conductive layers and the plurality of second via electrodes, extends in the stacking direction, and faces the plurality of semiconductor layers, wherein
the third via electrode is capable of being applied with a different voltage from the second via electrode.

10. The semiconductor memory device according to claim 9, wherein in a write operation,
at least a part of the plurality of conductive layers is applied with a first voltage,
the plurality of second via electrodes are applied with a second voltage smaller than the first voltage, and
the third via electrode is applied with a third voltage larger than the second voltage and smaller than the first voltage.

11. A semiconductor memory device comprising:
a plurality of semiconductor layers stacked in a stacking direction and extending in a first direction intersecting the stacking direction;
a plurality of conductive layers which are stacked in the stacking direction, extend in a second direction intersecting the stacking direction and the first direction, and are connected to end portions in the first direction of the plurality of semiconductor layers;
a plurality of first via electrodes which are arranged in the first direction along side surfaces in the second direction of the plurality of semiconductor layers, extend in the stacking direction, and face the plurality of semiconductor layers;
a plurality of electric charge accumulating layers provided between the plurality of semiconductor layers and the plurality of first via electrodes; and
a plurality of second via electrodes which are provided between the plurality of conductive layers and the plurality of first via electrodes, are arranged in the first direction along side surfaces in the second direction of the plurality of semiconductor layers, extend in the stacking direction, and face the plurality of semiconductor layers, wherein
in a first cross section extending in the first direction and the second direction, and including a first semiconductor layer of the plurality of semiconductor layers,
a part of a side surface on a plurality of second via electrodes side in the second direction of the first semiconductor layer lies along a plurality of circles whose center points overlap the plurality of second via electrodes and which have a first radius, and
a part of a side surface on an opposite side to the plurality of second via electrodes in the second direction of the first semiconductor layer lies along a plurality of other circles which are concentric with the plurality of circles and which have a second radius larger than the first radius.

12. The semiconductor memory device according to claim 11, further comprising
another via electrode which extends in the stacking direction and faces a side surface on an opposite side to the plurality of second via electrodes in the second direction of the first semiconductor layer.
